(19) United States
(12) Patent Application Publication
(10) Pub. No.: US 2026/0094791 A1
(43) Pub. Date: Apr. 2, 2026

(54) REMOVING METAL OXIDE FROM METALLIC CONTACTS ON SUBSTRATES, DIES AND WAFERS WITH ATMOSPHERIC PRESSURE PLASMA

(71) Applicant: Surfx Technologies LLC, Redondo Beach, CA (US)

(72) Inventors: Robert F. Hicks, Redondo Beach, CA (US); Alexander Mario Giordano, Cobleskill, NY (US); Thomas Scott Williams, Long Beach, CA (US); Hsiao-Wen Liu, Taichung City (TW)

(73) Assignee: Surfx Technologies LLC, Redondo Beach, CA (US)

(21) Appl. No.: 19/313,001

(22) Filed: Aug. 28, 2025

Related U.S. Application Data
(60) Provisional application No. 63/693,091, filed on Sep. 10, 2024.

(51) Int. Cl. H01J 37/32; H10W 72/00

(52) U.S. Cl. CPC H01J 37/32825; H01J 37/32449; H10W 72/01271; H10W 72/07125; H10W 72/07241; H01J 2237/335

(57) ABSTRACT

A method and device for modifying a surface of a substrate with a plasma in an inert gas environment, comprises enclosing the substrate in a chamber having surrounding sidewalls and a movable coverplate above the surrounding sidewalls with a gap therebetween, affixing a plasma source to the movable coverplate having a plasma outlet through the coverplate into the chamber, purging the chamber with inert gas sufficient to reduce an oxygen concentration of the chamber to several orders of magnitude less than in air, the inert gas entering through and inlet to the chamber and exiting through an outlet from the chamber, and scanning and activating the plasma source affixed to the cover plate over the substrate, such as to expose the surface of the substrate to a reactive species generated by the plasma delivered through the plasma outlet. An inert gas environment is maintained within the chamber throughout the scanning.

### CROSS-REFERENCE TO RELATED APPLICATION

This application claims the benefit under 35 U.S.C. § 119 (e) of the following U.S. provisional patent application, which application is incorporated by reference herein:

U.S. Provisional Patent Application No. 63/693,091, filed Sep. 10, 2024, and entitled “METHOD FOR REMOVING METAL OXIDE FROM METALLIC CONTACTS ON SUBSTRATES, DIES AND WAFERS WITH ATMOSPHERIC PRESSURE PLASMA,” by Hicks et al. (Attorney Docket No. SRFXP016.P1).

### BACKGROUND OF THE INVENTION

### 1. Field of the Invention

The invention is related to methods of using a purge chamber for plasma application to remove oxidation from copper, tin, tin and silver alloys, and indium for metal-metal bonding. Particularly, the invention is related to a reduction of copper oxide, tin oxide, tin-silver oxide and indium oxide for improved mechanical and electrical bonding in electronic assemblies such as flip chips.

### 2. Description of Related Art

Ionized gas plasmas have found wide application in materials processing. Plasmas that are used in materials processing are generally weakly ionized, meaning that a small fraction of the molecules in the gas are charged and balanced by free electrons such that the sum of the charges adds up to zero. In addition to the ions and free electrons, these plasmas contain reactive species that can clean, activate, etch and deposit thin films onto surfaces. The temperature in these weakly ionized gases is usually below 250° C., so that thermally sensitive substrates are not damaged. The physics and chemistry of weakly ionized plasmas are described in several textbooks. See for example, Lieberman and Lichtenberg, “Principles of Plasma Discharges and Materials Processing”, (John Wiley & Sons, Inc., New York, 1994), and Raizer, Y. P., “Gas Discharge Physics”, (Springer-Verlag, Berlin (1991).

According to the literature, weakly ionized plasmas are generated in vacuum at pressures between 0.001 and 1.0 Torr (see Lieberman and Lichtenberg (1994)). Electrical power is applied across two electrodes to break the gas down and ionize it. The electricity may be provided as a direct current (DC), alternating current (AC), radio frequency (RF) power, or microwave (MW) power. The electrode may be constructed to provide either capacitive or inductive coupling to strike and maintain the plasma. In the former case, two conducting electrodes are placed inside the vacuum chamber filled with a small amount of gas. One of the electrodes is powered, or biased, by the RF generator, while the other one is grounded. In the latter case, the RF power is supplied through an antenna that is wrapped in a coil around the insulating walls of the chamber. The oscillating electric field from the coil penetrates into the gas inducing ionization.

Over the past twentyfive years, atmospheric pressure plasmas have been developed as an alternative to vacuum plasmas. These plasmas can treat an object of any size and shape, since the object does not have to be loaded into a vacuum chamber. This can significantly reduce the cost of the process. A number of different atmospheric pressure plasma devices have been developed (Schutze, et. al., “The atmospheric-pressure plasma jet: A review and comparison to other plasma sources”, IEEE Trans. Plasma Sci. 26, 1685-1694 (1998)). These plasmas are governed by how the ionization process is controlled. At atmospheric pressure, the gas density is so high that the ionization reaction can easily run away and generate a high temperature arc, which is not useful in many cases for materials processing.

There are three common types of atmospheric pressure plasmas. These include a dielectric barrier discharge (DBD), a torch, and a radio-frequency, noble gas discharge. The DBD has long been employed to treat rolls of plastic film whereby the material is continuously passed between the electrodes. In some instances, the DBD may be deployed as a downstream device, so that 3-D objects can be treated with the reactive gas that flows out from between the electrodes. The torch and the RF noble-gas discharge are used to treat substrates placed downstream. In some cases, ions and electrons stream out of the torch to contact the substrate. On the other hand, in the noble-gas discharge the ions and electrons are confined to the gap between the electrodes so that the substrate is exposed to a beam of neutral reactive species (see for example, Cheng, et. al., U.S. Pat. No. 9,406,485, Aug. 2, 2016). A robot is used to scan the plasma beam over the substrate surface, which is positioned less than one centimeter below the plasma housing. In contrast to vacuum plasmas, only the area on the sample surface requiring treatment is exposed to the reactive gas species.

The dielectric barrier discharge is usually operated with air (See Goldman and Sigmond, “Corona and Insulation,” IEEE Transactions on Electrical Insulation, EI-17, no. 2, 90-105 (1982) and Eliasson and Kogelschatz, “Nonequilibrium Volume Plasma Chemical Processing”, IEEE Transactions on Plasma Science, 19, 1063-1077, (1991)). A 10 KV power supply operating at approximately 20 KHz supplies the voltage necessary to breakdown the gas. A dielectric barrier covers one of the electrodes, and prevents a high current arc from forming. During operation charges build up on the surface of the insulator and discharge as tiny “micro-arcs” within each AC cycle. The micro-discharges occur randomly in space and time, lasting for periods of 10 to 100 ns. Inside the micro-discharge, the electron density is high, whereas outside it is extremely low. Consequently, it is not possible to measure an average electron density and electron temperature for the entire gas volume between the electrodes. Note that substrates placed downstream of the DBD will not be treated uniformly with the plasma on the micro scale. In addition, the discharge can interact electrically with the substrate, making it difficult to treat components containing metals.

The torch is generated by forming an arc between closely spaced powered and grounded electrodes. This construct is described by Fauchais and Vardelle, in their article: “Thermal Plasmas”, IEEE Transactions on Plasma Science, 25, 1258-1280 (1997). Air is passed between the electrodes, and ionized by applying 10 kV AC power. The arc is a thermal plasma in which the neutral temperature is many thousands of degrees. Nevertheless, it is possible to blow gas through the arc at a sufficient velocity such that the overall gas temperature is low enough to treat thermally sensitive materials, including polymers. The PLASMAFLUME by PlasmaTreat is an example of this type of construct. It utilizes a rotating, cone-shaped electrode that rapidly spins the arc through the flowing gas volume, maintaining the average neutral temperature below 700 K. Plasma streamers with ions and electrons contained therein shoot out the end of the housing and treat objects placed a short distance below.

Atmospheric pressure, noble gas plasmas, driven with radio-frequency power at 13.56 or 27.12 MHz, operate in a different way than the DBD and torch plasmas. These plasmas are weakly ionized, capacitive discharges (see Jeong et al., “Etching Materials with an Atmospheric-Pressure Plasma Jet,” Plasma Sources Science Technol., 7, 282-285 (1998); Babayan et al., “Deposition of Silicon Dioxide Films with an Atmospheric-Pressure Plasma Jet,” Plasma Sources Science Technol., 7, 286-288, (1998); Moravej, et al., “Physics of High-Pressure Helium and Argon Radio-Frequency Plasmas”, J. Appl. Phys., vol. 96, p. 7011 (2004); Babayan and Hicks, U.S. Pat. No. 7,329,608, Feb. 12, 2008, Babayan and Hicks, U.S. Pat. No. 8,328,982, Dec. 11, 2012, and Cheng et. al., U.S. Pat. No. 9,406,485, Aug. 2, 2016). The ions and electrons uniformly fill the gas volume between the metal electrodes, with a collisional sheath forming at the boundaries to repel the electrons and maintain the plasma. The average electron density and temperature in the RF, noble gas plasma has been determined to be 1011 to 1012 cm-3 and 1 to 2 eV, respectively. Depending on the RF power level, the neutral gas temperature ranges from 323 to 573 K. Molecular gases are fed with the helium or argon at concentrations from 0.1 to 5.0 volume %.

Semiconductor materials, such as silicon, are processed in vacuum plasmas by inserting them into a chamber supplied with powered and grounded electrodes, striking the discharge by applying power to the electrodes, and then running the plasma for several minutes to modify the material surface. Silicon substrates are provided as thin wafers in discrete sizes of 100, 150, 200 and 300 mm in diameter. The vacuum chamber is designed specifically to fit wafers of a given size. One way to clean a silicon surface is to feed oxygen and argon to the chamber. Energetic free electrons in the plasma convert a portion of the oxygen molecules to oxygen atoms and other reactive species that attack the organic contaminants on the surface and convert them into gaseous carbon dioxide. In addition, the surface may be physically sputtered of contaminants by bombardment of the substrate with positively charge argon ions (Art). Following oxygen plasma treatment for several minutes in the vacuum chamber, the silicon wafer surface is clean and activated for other semiconductor processing steps.

Another way to clean the surface of a semiconductor material is to insert the substrate into the vacuum chamber and to strike the plasma with a feed gas containing a mixture of hydrogen and argon. In this case, the energetic free electrons will produce H atoms and Art ions that will strike the surface of the substrate and remove metal oxide contaminates, including, but not limited to, copper oxide, silver oxide, tin oxide, or indium oxide. To prevent a safety hazard by introducing a flammable mixture of hydrogen into a chamber, the feed gas to the plasma must contain less than 4.0% H₂ in argon. At the operating pressure of the vacuum chamber, 0.05 to 0.50 Torr, the resulting concentration of hydrogen is only 2 to 20 milliTorr. Thus, the supply of active hydrogen atoms and in turn the rate of hydrogen atom etching of the metal oxide will be extremely low, so that most of the oxide contaminant must be removed by sputtering.

Another drawback of vacuum plasma processing of materials is that the chamber becomes dirty upon repeated processing of the silicon wafers. The chamber slowly fills up with particles (i.e. contamination) ranging in size from 0.01 to 10.0 microns in diameter. This problem has been documented in many publications (see for example, G. S. Selwyn, et al., J. Vac. Sci. Technol. A 7, 2758 (1989); ibid., 8, 1726 (1990); M. J. McCaughey and M. J. Kushner, Appl. Phys. Lett. 55, 951 (1989); R. N. Nowlin and R. N Carlile, J. Vac. Sci. Technol. A 9, 2824 (1990); G. S. Selwyn, Jpn. J. Appl. Phys. 32, 3068 (1993); and S. J. Choi, et al., Plasma Sources Sci. Technol. 4, 418 (1994); and R. L. Merlino and J. A. Gorce, Physics Today 1 (July 2004)). When the plasma is turned on, the particles become negatively charged and as a result of the electric field in the chamber, the particles float over the wafer surface. When the plasma is turned off, the particles drop down on the wafer, forming a layer of contamination. It is well known to those skilled in the art that particles present during wafer processing can kill solid-state devices. The semiconductor industry is obsessed with eliminating them, and spends billions of dollars constructing cleanrooms that are free of particles above 0.01 microns in diameter. Dirty plasma chambers must be routinely cleaned to reduce particle contamination. In addition, wafers may need to be wet cleaned after plasma immersion to eliminate any particles that are stuck on them. All this drives up the cost of manufacturing semiconductor devices.

A fabrication process that would greatly benefit from metal oxide removal via hydrogen plasma is flip chip interconnect bonding. In this process, one chip with a two-dimensional array of solder balls or bumps, with a distance between the center of the balls or bumps of less than 200 microns, is placed on another chip or substrate with a two-dimensional array of metal pads or bumps having the same spacial arrangement. The chips are then heated and pressed together to form an intermetallic metal interconnect across each ball or bump (J. H. Lau, “Semiconductor Advanced Packaging,” (Springer Nature, Singapore, 2021). Oxide layers on the metal surfaces must be removed prior to bonding to ensure that ohmic contacts are made that are mechanically strong and exhibit minimal electrical resistance. Metal oxidation on the balls or bumps is normally removed by incorporating organic flux within the solder. During reflow, the organic flux reacts with the metal oxide forming a compound that sublimes off the surface leaving bare metal behind. However, flux produces organic residues during reflow that must be removed by a washing step. When the distance, or pitch, between the balls or bumps is less than 50 microns, it is no longer possible to remove these organic residues by washing. In this case, hydrogen plasma removal of the metal oxide would be an excellent alternative to flux. However, using a vacuum plasma for this process is ineffective, because as noted above, the hydrogen radical concentration is so small that the etch rate is too slow, and sputtering must be employed instead. Sputtering is not a self-limiting process and can easily damage the semiconductor materials. Furthermore, the flip chips with the ball grid arrays must be transferred from vacuum to a thermocompression bonder, where it is likely that the metal balls reoxidize before they can be bonded together.

An atmospheric pressure, noble gas plasma fed with hydrogen can be used to remove oxidation from metals, such as copper oxide from copper and indium oxide from indium (see for example, Cheng et. al, U.S. Pat. No. 9,406,485, Aug. 2, 2016, and Schulte, U.S. Pat. No. 8,567,658, Oct. 29, 2013). This process can be used to remove oxidation from ball grid arrays or micro-bump arrays prior to flip chip bonding. The advantage of the atmospheric pressure hydrogen and noble-gas plasma is that the concentration of hydrogen radicals is much higher than in vacuum, and no sputtering occurs that could damage the semiconductor devices. Nevertheless, it is possible that the metal balls or bumps may reoxidize during transfer from the plasma to the thermocompression bonder. Schulte (U.S. Pat. No. 8,567,658, Oct. 29, 2013) teaches that a passivation step is needed using an “activated chemical passivation agent” to prevent reoxidation during transfer from the plasma processing step to the bonding step. Depending on the combination of metallic elements used in the ball or micro-bump arrays the passivation step may or may not be effective at achieving mechanically strong metal interconnects with minimal electrical resistance.

In view of the foregoing, there is a need for an apparatus and method that can rapidly remove the oxidation from metal interconnect arrays using hydrogen plasma at atmospheric pressure, then transfer the deoxidized metal balls or bumps on the chips and/or substrate to the bonder where they are bonded to make a high-density interconnect array. Furthermore, this apparatus and method must be suitable for materials processing, and not damage the semiconductor chips by ion bombardment, electrostatic discharge, particle contamination, or ultraviolet light exposure. Particularly, there is a need for an apparatus and methods that enable the removal of copper, silver, tin and indium oxides from arrays of metallic balls or bumps with subsequent thermocompression bonding to form mechanically strong and conductive metallic interconnects. Such an apparatus and methods have particular application in flip chip bonding involving two-dimensional arrays of closely spaced interconnects. These and other needs are met by embodiments of the present invention as described hereafter.

### SUMMARY OF THE INVENTION

Methods and apparatus for plasma treatment and bonding of electrical interconnects for integrated circuit packages such as flip chips are disclosed. A method of interconnect bonding includes applying a plasma comprising activated hydrogen via an atmospheric pressure plasma applicator to a first metallic contact supported on a substrate to remove oxidation and create a newly deoxidized metal surface. Then the first metallic contact is bonded to a second metallic contact via the application of mechanical force, heat, or both, such as by thermocompression bonding (TCB). An inert gas environment is formed within an enclosure for application of the plasma, and a second inert gas environment is formed within an enclosure for bonding of the first metallic contact to the second metallic contact. The substrates for the first metallic contact and the second metallic contact may be selected from the group consisting of, but not limited to, semiconductor dies (also known as integrated circuits or chips), semiconductor wafers, such as 300 mm silicon wafers with integrated circuits on them, organic or plastic substrates, ceramic substrates, lead frames, and printed circuit boards (PCBs).

A exemplary method for modifying a surface of a substrate with a low temperature, atmospheric pressure plasma in an inert gas environment, comprises enclosing the substrate in a chamber having surrounding sidewalls and a movable coverplate above the surrounding sidewalls with a gap therebetween, affixing a plasma source to the movable coverplate having a plasma outlet through the coverplate into the chamber, purging the chamber with inert gas sufficient to reduce an oxygen concentration of the chamber to several orders of magnitude less than in air, the inert gas entering through and inlet to the chamber and exiting through an outlet from the chamber, and scanning and activating the plasma source affixed to the cover plate over the substrate, such as to expose the surface of the substrate to a reactive species generated by the plasma delivered through the plasma outlet. An inert gas environment is maintained within the chamber throughout the scanning.

In another embodiment of the invention, the application of the plasma to remove oxidation from the first metallic contact supported on a substrate and the bonding of the first metallic contact on the first substrate to the second metallic contact on the second substrate is carried out in an enclosure maintained in an inert gas environment throughout the entire process. The substrates may be selected from the group consisting of, but not limited to, semiconductor dies, semiconductor wafers, plastic substrates, ceramic substrates, lead frames, and printed circuit boards (PCBs).

In another embodiment of the invention, a method of interconnect bonding includes applying a plasma comprising activated hydrogen via an atmospheric pressure plasma applicator to a first metallic contact supported on a substrate and to a second metallic contact supported on a substrate to remove oxidation from both metallic contacts and create newly deoxidized metal surfaces. Then the first metallic contact is bonded to the second metallic contact via the application of mechanical force, heat, or both, for example by TCB. An inert gas environment is formed within an enclosure for application of the plasma to both metallic contacts and for bonding of the first metallic contact to the second metallic contact.

A typical embodiment of the invention comprises a method of interconnect bonding including the steps of applying a plasma comprising activated hydrogen via an atmospheric pressure plasma applicator to at least a first metallic contact supported on a first substrate to remove oxidation and create a newly deoxidized metal surface on the first metallic contact, bonding the first metallic contact to a second metallic contact supported on a second substrate with application of mechanical force, heat, or both to the first metallic contact in contact with the second metallic contact, and forming an inert gas environment within which said application of the plasma is performed and within which said bonding of the first metallic contact to the second metallic contact is performed, wherein bonding the first metallic contact to the second metallic contact forms a metal interconnect between the first metallic contact and the second metallic contact.

In this embodiment, the first and second substrates may be chips and the metallic contacts on the chips are bonded together to form a chip-on-chip (CoC) package; or the first substrate may be a chip and the second substrate may be a wafer and the metallic contacts are bonded together to form a chip-on-wafer (CoW) package; or the first and second substrates may be wafers and the metallic contacts on the wafers are bonded together to form a wafer-on-wafer (WoW) package; or the first substrate may be a chip and the second substrate may be a board and the metallic contacts are bonded together to form a chip-on-board (CoB) package. These and other interconnect packages would be obvious to those with ordinary skill in the art. Embodiments of the invention can further encompass apparatus embodiments consistent with any of the method embodiments described herein.

In further embodiments, the inert gas environment can comprise less than 500 parts per million (ppm) of oxygen, and preferably less than 100 ppm of oxygen. Furthermore, the inert gas environment can be generated by mounting the atmospheric pressure plasma applicator, the first substrate supporting the first metallic contact, and the second substrate supporting the second metallic contact inside a volume that is purged with an inert gas flow, wherein air initially inside the volume is displaced by the inert gas flow. The inert gas flow can be selected from the group comprising argon and nitrogen.

In other embodiments, the application of the plasma can be performed by sweeping said atmospheric pressure plasma applicator across said first substrate supporting the first metallic contact. In addition, the activated hydrogen can be formed by feeding hydrogen gas in a concentration of 0.1 to 2.0% in argon gas to the plasma. Contacting of the first metallic contact with the second metallic contact for bonding can occur at a temperature between 2° and 250° C. Further, the first metallic contact and the second metallic contact can each comprise a metal or metal alloy selected from the group comprising cobalt, nickel, copper, rhodium, palladium, silver, iridium, platinum, gold, indium, tin, antimony, lead, and bismuth.

In some embodiments, the first metallic contact on the first substrate can comprise a two-dimensional array of metallic bumps with a center-to-center distance between the metallic bumps of 2 to 100 microns. The first substrate can be kept in the inert gas environment separately during application of the plasma and bonding of the first metallic contact to the second metallic contact on the second substrate. In another embodiment, the first substrate and the second substrate can be kept in the inert gas environment throughout application of the plasma and bonding of the first metallic contact on the first substrate to the second metallic contact on the second substrate. The plasma comprising the activated hydrogen via the atmospheric pressure plasma applicator can also be applied to the second metallic contact on the second substrate and said second substrate held within the inert gas environment throughout application of the plasma and bonding of the first metallic contact to the second metallic contact. In a typical embodiment, the first metallic contact on the first substrate and the second metallic contact on the second substrate can comprise a flip chip assembly.

In further embodiments, the first metallic contact on the first substrate and the second metallic contact on the second substrate can each comprise a two-dimensional array of metallic bumps with a center-to-center distance between the metallic bumps of 2 to 100 microns, and bonding the first metallic contact to the second metallic contact comprises the metallic bumps of the first metallic contact being aligned with and bonded to the metallic bumps of the second metallic contact. Further, the two-dimensional array of the second metallic contact can comprise an under-bump metallization comprising metal pads.

In one embodiment, the atmospheric pressure plasma applicator can comprise an atmospheric pressure plasma head affixed to a cover plate having a slotted passage for the plasma to pass therethrough to the first metallic contact supported by the first substrate. The cover plate can include at least one purge hole for an inert gas to pass therethrough to form the inert gas environment. The cover plate can include at least one sampling hole therethrough to measure and confirm that the oxygen concentration is below 500 ppm. Application of the plasma can be performed by scanning the slotted passage across said first metallic contact on said first substrate. The cover plate may sit atop an enclosed volume in which said first substrate is inserted, wherein the distance from the top of the substrate to the slotted passage is no more than 10 millimeters. It should be obvious to those with ordinary skill in the art that the enclosed volume should be sufficient to fit the substrate, but no larger than that needed to scan the plasma head mounted on the cover plate across the substrate surface at a distance of 0.5 to 10.0 millimeters. After treatment of the metallic contacts on the first substrate, the apparatus embodied in the invention has a means of moving said first substrate onto the second substrate, aligning the metallic contacts on the first substrate with the metallic contacts on the second substrate and bonding them together to form metal interconnects by application of mechanical force, heat, or both, with all steps taking place in an inert environment, having an oxygen concentration less than 500 ppm.

In another embodiment, the atmospheric pressure plasma applicator can comprise an atmospheric pressure plasma head affixed to the bottom of an enclosed volume with the plasma beam directed upwards through a slotted passage. The plasma exit gas flows up through the slotted passage and brushes against the first metallic contact on the first substrate. In this case, the first substrate is attached to a bond head mounted on a cover plate. Said first substrate protrudes into the enclosed volume with a distance from the slotted passage that is no more than 10 millimeters, and preferably between 1 and 4 millimeters. The apparatus embodied in this invention comprises a means of sweeping the first substrate over the plasma beam containing the activated hydrogen so as to remove oxidation from the first metallic contact, then aligning the first metallic contacts on the first substrate with the second metallic contacts on the second substrate, and bonding them together to form metal interconnects by application of mechanical force, heat, or both, with all steps taking place in an inert gas environment, having an oxygen concentration less than 500 ppm.

### BRIEF DESCRIPTION OF THE DRAWINGS

Referring now to the drawings in which like reference numbers represent corresponding parts throughout:

FIG. 1. illustrates an exemplary plasma process for removing a metal oxide layer from a metal;

FIG. 2 is a schematic of an exemplary apparatus for exposing a substrate to the activated gases from an atmospheric pressure hydrogen and argon plasma in which air has been removed from the treatment area by a localized inert gas purge;

FIG. 3A is a picture of a tin solder bump before removal of the tin oxide on the surface with the atmospheric pressure hydrogen and argon plasma;

FIG. 3B is a picture of a tin solder bump after the tin oxide has been removed with the atmospheric pressure hydrogen and argon plasma;

FIG. 4A is an x-ray photoemission spectrum of tin 3d peaks for an oxidized tin surface;

FIG. 4B is an x-ray photoemission spectrum of tin 3d peaks for a tin that has been scanned with the atmospheric pressure hydrogen and argon plasma;

FIG. 4C is an x-ray photoemission spectrum of tin 3d peaks for a tin surface that has been scanned with the atmospheric pressure hydrogen and argon plasma and then allowed to sit in air at room temperature for 30 hours;

FIG. 5A shows an optical microscope image of tin solder bumps after heating to 250° C. in an inert gas environment.

FIG. 5B shows an optical microscope image of tin solder bumps after heating to 250° C. in an inert gas environment and exposing it to the atmospheric pressure hydrogen and argon plasma at 250° C.;

FIG. 6A illustrates a poor metal-metal bond resulting from the thin tin-oxide layer that rapidly forms when air exposure is allowed between plasma treatment and reflow bonding;

FIG. 6B illustrates a robust metal-metal bond when there is no air exposure between treatment with the atmospheric pressure hydrogen and argon plasma and reflow bonding of the micro-bump array to the copper substrate;

FIG. 7A is an optical micrograph of indium bumps after heating to 165° C. in an inert gas environment;

FIG. 7B is an optical micrograph of indium bumps after treatment with the atmospheric pressure hydrogen and argon plasma at 165° C. in an inert gas environment;

FIG. 8 compares the relative shear strength to the relative bond force applied to two-dimensional indium bump arrays bonded by thermocompression at room temperature;

FIG. 9 shows the relative shear strength of indium-to-UBM bonded assemblies with no plasma treatment (control), hydrogen plasma treatment of the indium bumps only, and hydrogen plasma treatment of both the indium bumps and the UBM;

FIG. 10 shows the relative shear strength for indium-to-indium micro-bump assemblies when exposed to air for different times between hydrogen plasma cleaning and thermocompression bonding;

FIG. 11 is a schematic of an apparatus for atmospheric pressure hydrogen and argon plasma processing of a substrate or die held within an inert gas purged environment;

FIGS. 12A and 12B illustrate top and isometric views, respectively, of a recessed volume for mounting a die in the apparatus for atmospheric pressure hydrogen and argon plasma treatment in an inert gas environment;

FIGS. 13A and 13B illustrate top isometric and bottom isometric views, respectively, of the assembled cover plate and plasma head;

FIG. 14 is a schematic of an apparatus for atmospheric pressure hydrogen and argon plasma processing of silicon wafers in an inert gas purged environment;

FIG. 15 shows a layered cross section of the apparatus for atmospheric pressure hydrogen and argon plasma processing of wafers in an inert gas purged environment;

FIG. 16 shows a cutaway view of the apparatus for atmospheric pressure hydrogen and argon plasma treatment wherein the silicon wafer is mounted inside the inert gas purged environment;

FIG. 17 shows a side view of the apparatus for atmospheric pressure hydrogen and argon plasma treatment wherein the silicon wafer is mounted inside the inert gas purged environment;

FIG. 18 shows an expanded side view of the apparatus for atmospheric pressure hydrogen and argon plasma treatment of wafers, in which the inert gas purge flow is highlighted;

FIG. 19 shows top and side views of the wafer holder with the inert purge gas flow entering on the left side and uniformly flowing over the wafer from left to right;

FIG. 20 illustrates the path that the 100 mm linear plasma head and cover plate are moved to fully scan over a 300 mm silicon wafer;

FIG. 21 illustrates an example of four Cu-coated Si wafers before processing with the argon and hydrogen plasma in the exemplary plug flow purge chamber; and

FIG. 22 illustrates an example of four Cu-coated Si wafers after processing with the argon and hydrogen plasma in the exemplary plug flow purge chamber.

### DETAILED DESCRIPTION INCLUDING THE PREFERRED EMBODIMENTS

### 1.0 Overview

The described embodiments hereafter only illustrate examples for practicing the invention. Those skilled in the art will appreciate how the described examples can be readily applied in a wide range of other applications. Notably, the described atmospheric pressure plasma deoxidation processes and apparatus can be applied to semiconductor packaging applications including, but not limited to, flip chip bonding. As known in the art, flip chip bonding offers advantages compared to other interconnection processes. This method uses the entire area of the die rather than making connections only at the perimeter of an integrated circuit. Accordingly, flip chip bonding provides a higher density of interconnects, and the interconnect paths are shorter compared to wire bonds, which enables faster device speeds. Integrated circuit manufacturing processes which are efficient and cost effective and can be used to improve the quality and performance of the interconnects such as those described herein have significant value to electronics production.

Typically, all the bonding for flip chip packages is completed in a single process rather than making individual connections sequentially. Solder bumps for flip chip bonding are typically comprised of a metal with a low melting point, often consisting of indium, tin, or other suitable alloys. After aligning and placing the chip, the electrical connection is made by heating past the solder melting point, or by using thermocompression bonding (TCB) at temperatures below the melting point. The presence of metal oxide on the solder bump surface impedes both such techniques by preventing the complete melting of the solder bump in the case of reflow, or by increasing the required force necessary to break through the surface oxide for TCB.

Organic fluxes are often used to remove metal oxides when making solder bump connections. However, the flux leaves behind corrosive residues that can damage nearby components and/or cause shorts between the interconnects. Consequently, these residues must be washed away after bonding. With a trend towards smaller and smaller solder bumps and smaller pitch sizes between the bumps, solder residue removal has become a major roadblock due to the difficulty of introducing wet chemical solutions within the microscopic volume between the flip-chip and the substrate. In particular, high surface tension prevents the liquid from penetrating into these tiny spaces.

Flip-chip bonding without using an organic flux embedded in the solder is becoming an attractive option for smaller pitch sizes. One such example is removing the metal oxide from the solder bump surfaces via contact with formic acid vapor. Here the formic acid and metal oxide react with each other, forming a metal formate that sublimes off the surface. Unfortunately, this process requires temperatures above 200° C. in order to achieve a significant reaction rate. In addition, processing with formic acid vapor can still leave behind organic residues, and may corrode the solder surface and other exposed metals during the reaction.

The atmospheric pressure plasma process embodied herein uses activated hydrogen gas to react with the metal oxide, converting it to metal and water vapor that leaves the system. This process can occur at lower temperatures than the formic acid vapor process described above. Furthermore, no organic residues are created, and no corrosion occurs of any metal components in the integrated circuit. By carrying out the process in an inert gas environment of argon or nitrogen, the metal oxide is removed and no further oxidation occurs prior to bonding the metallic contacts together to form the interconnects.

### 2.0 Apparatus and Method of Removing Surface Oxide from Tin and Tin/Silver Alloys

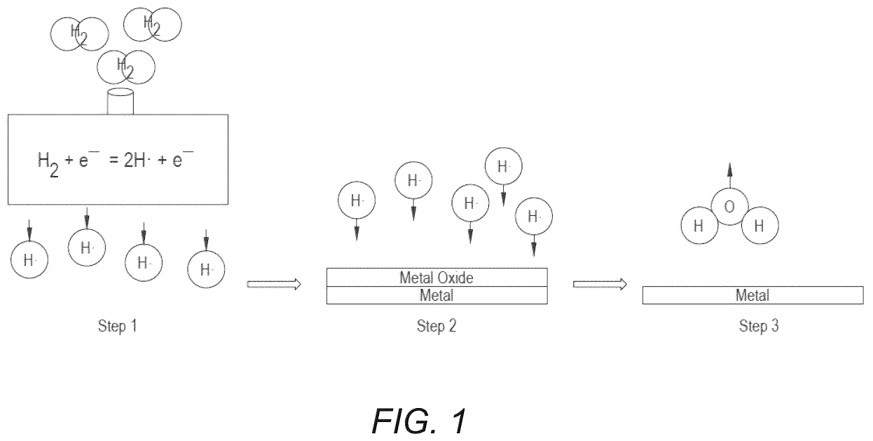

FIG. 1 shows a schematic of an exemplary metal oxide removal process. Hydrogen molecules in a concentration of 0.1 to 2.0 volume % are fed in argon to an atmospheric pressure plasma head that is driven with radio frequency power, for example at 27.12 MHz. The radio frequency power causes the gas to become ionized inside the head, generating positive and negative ions and free electrons. The free electrons collide with the H₂ molecules causing them to dissociate into radicals, H·, as indicated in step (1). The hydrogen radicals flow out of the plasma device and contact the metal oxide on the balls or bumps of the substrate in step (2). In step (3), the hydrogen radicals react with the oxygen contained in the metal oxide to produce water, H₂O, leaving behind the bare metal. In the case of tin oxide on tin or tin-silver alloys, the hydrogen radicals react with tin oxide, SnO or SnO₂, to produce tin (Sn) metal and H₂O according to the stoichiometry of the reaction. Any silver oxide present is reduced to silver metal as well. Moreover, if there is residual organic contamination on the surface this can be quickly removed by the hydrogen radicals. A sufficient time for exposure of the metallic contacts on the substrate to the reactive hydrogen species may be from 0.01 seconds to 1.0 minute, and generally is in the range of 0.1 to 3.0 seconds. During contacting of the metallic contacts on the substrate, which alternatively may be a chip, or a wafer, the atmospheric pressure plasma may be scanned over the substrate, die, or wafer to uniformly contact the metal oxide surfaces on the balls or bumps with the hydrogen radicals.

Hydrogen gas is particularly well suited for carrying out the metal oxide removal process. However, other molecules containing hydrogen could be used, such as ammonia (NH₃), or hydrogen sulfide (H₂S), and would be obvious to those skilled in the art. Atmospheric pressure plasmas suitable for embodiments of the invention include those that generate a high concentration of ground-state atoms, radicals, or metastable molecules containing active hydrogen downstream of the plasma head.

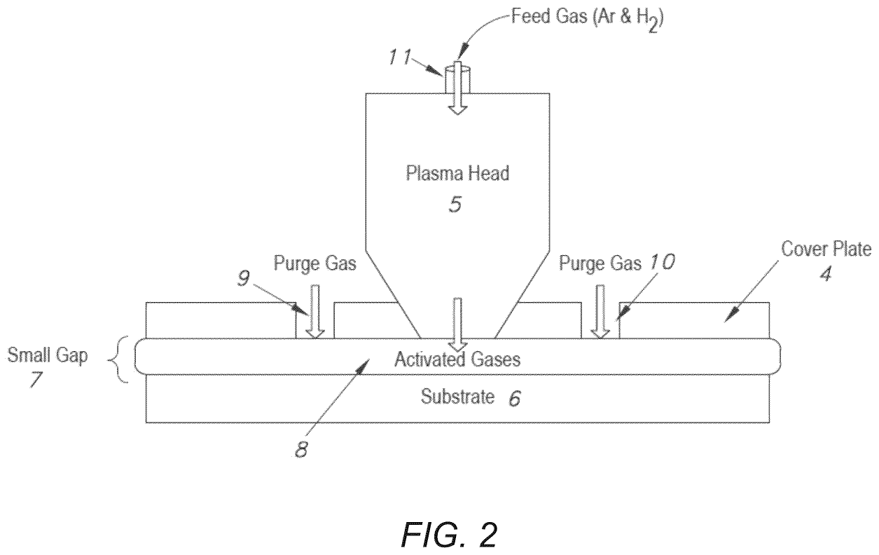

In FIG. 2, a schematic is presented of an exemplary apparatus which combines an inert gas purged environment with the activated hydrogen gas from the plasma to remove the metal oxide. The apparatus consists of a cover plate 4 that is attached directly to the plasma head 5. Feed gas, containing argon and 0.1 to 2.0% hydrogen, enters the plasma head 5 at the inlet 11, and is converted into a weakly ionized plasma, producing free electrons, ions and activated gases comprising at least a suitable concentration of hydrogen radicals. The activated gases 8 flow out of the plasma head 5 and contact the substrate 6. The cover plate 4 and plasma head 5 are flush with each other and are mounted above the substrate 6, maintaining a small gap 7 between the plasma head 5 and substrate 6. Air is quickly displaced from the gas volume in the small gap 7 by the activated gas flow. Suitable gap spacings are 0.1 to 5.0 mm, and preferably between 0.1 and 2.0 mm. Additional purge gas may be introduced through purge holes 9 and 10 in the cover plate 4. The purge gas is selected from the group of inert gases, argon and nitrogen. The purge gas assists the activated gas in displacing air from the gas volume in the gap 7, such that an inert gas environment is maintained during removal of the metal oxide from the metallic contacts by the activated hydrogen. An inert gas environment is defined as one where the oxygen concentration is low enough to not cause reoxidation of the metal contacts after exposure to the activated hydrogen generated by the plasma process. Examples of an inert gas environment is where the oxygen concentration is below 500 ppm, and preferably below 100 ppm. Exemplary purge holes 9 and 10 can comprise elongated slits or one or more holes through which the purge gas flows around the activated gases 8.

A slight positive pressure is established within the gap 7 such that there is sufficient gas flow to expel all the air out the perimeter of the cover plate 4. This allows the plasma reduction process to occur in an inert gas environment with a concentration of oxygen below 500 ppm. The low oxygen environment facilitates the removal of the metal oxide and prevents re-oxidation of the metal particularly when the substrate 6 is heated.

In practice, substrates to be treated may be conveyed through the apparatus while the atmosphere surrounding the substrates is continuously exchanged, and a low oxygen environment is maintained prior to subsequent reflow or compression bonding operations. The apparatus containing the atmospheric pressure hydrogen and argon plasma may be operated as an independent unit for tin oxide removal from tin or tin/silver alloy bumps. After tin and/or silver oxide removal, the substrate is transferred at ambient conditions to the bonding operation. In another preferred embodiment of the invention, the apparatus containing the plasma head is integrated with the bonding operation so that the substrate may be kept in an inert gas environment during plasma treatment, transfer to the bonding zone, and bonding of the metallic contacts together.

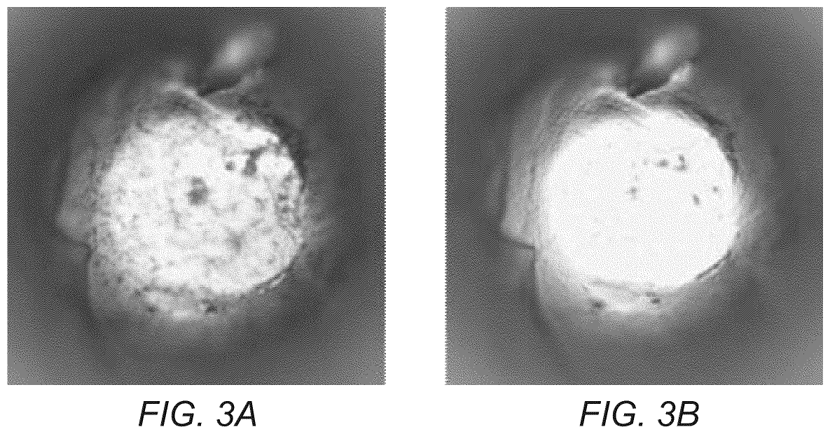

In FIGS. 3A and 3B, optical micrographs are shown of tin solder bumps before and after plasma oxide removal, respectively. The image in 3A is of a solder bump covered with tin oxide, as evidenced by the yellow color, and rough mottled appearance. Following removal of the tin oxide with activated hydrogen from the atmospheric plasma, the solder bump is smooth with a highly reflective metallic silver color.

An example embodiment of the invention is the treatment of tin metal films with the atmospheric pressure argon and hydrogen plasma in a purged environment. A thin native oxide layer exists on the surfaces of the tin films. The atmospheric plasma head is mounted on a cover plate with the purge gases as shown on FIG. 2. Then the head and cover plate are affixed to a scanning robot so that the activated gases may be swept over the samples without air present. In this example, a linear plasma source is used whereby the activated hydrogen gas flows out of a slit 100 mm in width. The distance between the outlet slit and the tin surface is approximately 1.0 mm. The plasma source is scanned over the substrate at room temperature at different scan speeds ranging from 0.25 to 10.0 mm/s. The plasma source is fed with 40.0 liters per minute (LPM) of argon and 0.40 LPM of hydrogen. Radio frequency power at 500 W (27.12 MHz) is supplied to the plasma head to strike and maintain the gas discharge.

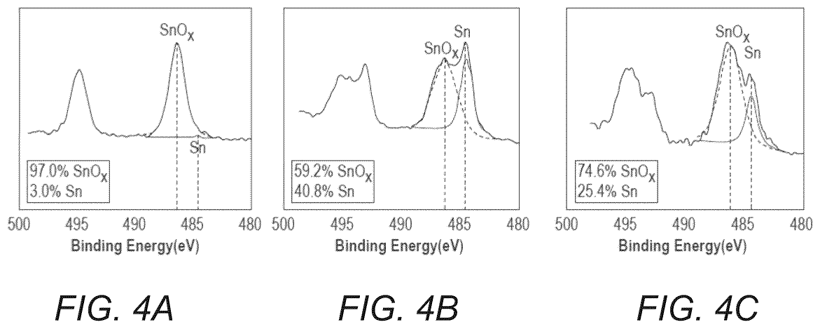

Shown in FIGS. 4A, 4B and 4C are x-ray photoemission spectra of the Sn 3d_{3/2} and 3d_{5/2} peaks for the surface of a tin film after formation of the native oxide, following hydrogen plasma reduction of the native oxide, and following 30 hours of aging the native oxide in air after plasma reduction, respectively. In FIGS. 4B and 4C, the Sn 3d_{5/2} peaks have been deconvoluted to show the presence of two separate peaks at 486.7 eV and 485.0 eV. The peaks for oxidized tin, SnO and SnO₂, are very close together and so the single broad peak at 486.7 eV is attributed to oxidized tin (SnO_{X}). The peak at 485.0 eV is due to metallic tin (Sn). A significant change can be seen between the tin peak before and after treatment with the argon and hydrogen plasma. Before plasma treatment, little if any photoemission from metallic tin is evident. Whereas after plasma treatment, a large peak at 285.0 eV due to metallic tin can be seen. These results are in good agreement with the previous studies of surfaces exposed to hydrogen plasmas in vacuum.

TABLE 1 provides an estimate of the relative fractions of metallic tin and tin oxide estimated from the areas of the deconvoluted Sn 3d_{5/2} peaks. The results show that hydrogen plasma reduction at atmospheric pressure increases the fraction of metallic tin from 3.0% to 40.8%. The increase in the metallic tin indicates that the thickness of the oxide surface layer has been substantially reduced. This thinner oxide layer can be more easily broken through when upon thermocompression bonding of tin or tin-silver bumps to each other. Significant regrowth of the oxide layer occurred during 30 hours of exposure of the tin films to air after hydrogen plasma treatment. In this case the fraction of metallic tin detected decreases from 40.8% to 25.4%. These results suggest that the time between oxide removal with the hydrogen plasma and bonding should be kept as short as possible, preferably less than one hour.

TABLE 1
Composition of the different tin surfaces determined
by deconvolution of the Sn 3d_{5/2} photoemission peak.

| Condition | Sn | SnO_{X} |
|---|---|---|
| Oxidized | 3.0% | 97.0% |
| H₂/Ar plasma reduction | 40.8% | 59.2% |
| 30 hours after H₂/Ar plasma reduction | 25.4% | 74.6% |

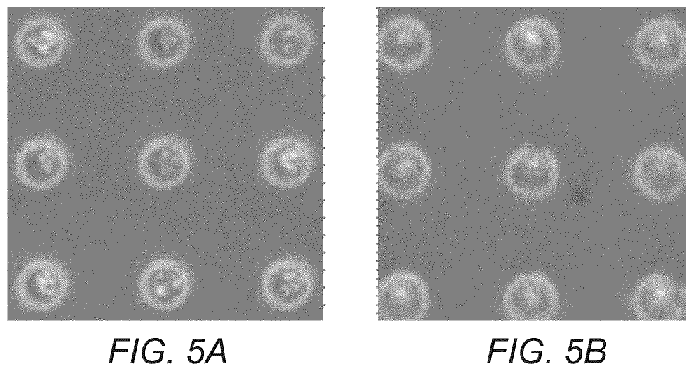

FIGS. 5A and 5B show images of tin solder bumps taken with an optical microscope. The image in FIG. 5A is of tin solder bumps that have been heated to 250° C. in an inert gas environment. Whereas the image in FIG. 5B is of tin solder bumps that have been treated with the atmospheric pressure hydrogen and argon plasma at a temperature of 250° C. all the while maintaining the sample in an inert gas environment. The plasma process was carried out using a 100-mm-wide linear beam running at 500 W, 40 L/min of argon and 0.4 LPM of H₂. The gap between the plasma head and the sample was 1.5 mm. The tin solder bumps in FIG. 5A are heavily oxidized as evident by their rough, flat top with multiple small bumps. By contrast, the bumps seen in FIG. 5B have a smooth, spherical shape with a highly reflective surface. The spherical shape is evidenced by the intense light reflection near the center of the bump surrounded by a dark ring caused by the highly angled sides. These results demonstrate the ability of the atmospheric pressure hydrogen and argon plasma process to completely remove the metal oxide from the tin solder bumps.

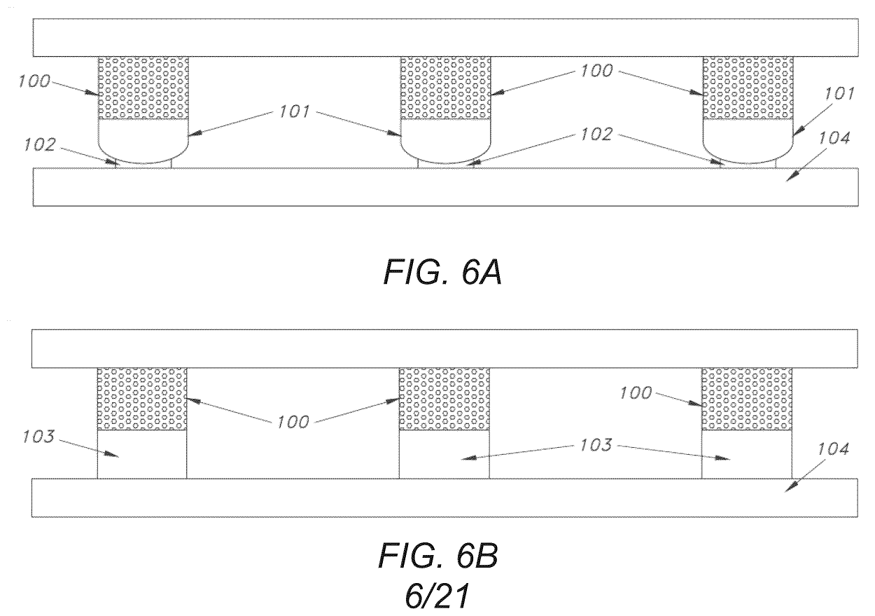

The surface tension forces involved during tin solder reflow are much smaller than the forces which are applied during thermocompression bonding. Unlike thermocompression bonding, the tin solder bump surface must be completely free of oxide for the reflow process to work. Accordingly, the substrates must be maintained in an inert gas environment throughout removal of the oxide by activated hydrogen from the plasma and bonding of the tin solder to the substrate. These findings are illustrated in FIGS. 6A and 6B. In this experiment, a first substrate comprised a two-dimensional array of copper pillars 100 with tin caps 101, while a second substrate comprised a silicon die coated with a thin film of copper 104. After treating both substrates with the activated hydrogen from the atmospheric pressure hydrogen and argon plasma, the first substrate was placed on top of the second substrate and the package heated above 200° C. Note that the first substrate was placed top down so that the tin caps 101 are in direct contact with the copper film 104. Shown in FIG. 6A is the result obtained when hydrogen plasma cleaning and reflow are carried out in an inert gas environment but transfer from one process to the other occurs in air. In this case, the tin solder slightly wets the copper film forming a weak tin bond 102 to the copper surface. Shown in FIG. 6B is the result obtained when the hydrogen plasma cleaning, reflow process and transfer step are all carried out in an inert gas environment. Here, the tin solder fully wets and bonds to the copper forming an intermetallic, SnₓCu_{y}, joint 103 between the two substrates. This latter case is required for making suitable micro-bump interconnects for flip chips.

### 3.0 Method of Removing Surface Oxide from Indium

Another embodiment of the invention is removing the surface oxide from indium bumps prior to bonding. It was discovered that passivation of the surface is not necessary for the interconnect bonds to be made. Surface indium oxide layers are removed through atmospheric pressure hydrogen and argon plasma exposure in an inert gas environment. Indium metal has a melting point of 157° C. With its low melting point, indium may be substituted for tin when the semiconductor package is thermally sensitive, such as is the case for some imaging sensors. However, indium oxide has a melting point of 1910° C., so any surface oxide on the indium metal means that the solder bumps will not form an intermetallic bond unless the oxide is removed. Once the oxide has been reduced, as with tin, reflow bonding or thermocompression bonding can be used to make strong electric and mechanical connections.

Indium solder bumps were placed on a hot plate and heated to 160° C. At this temperature, the metallic indium becomes molten, but the surface oxide layer remains solid. The oxide layer forms a thin skin on the surface of the molten indium interior, preventing the solder bump from reflowing and changing shape. To remove the surface oxide, a gas flow containing 32.4 LPM argon and 7.0 LPM forming gas (5% hydrogen in 95% argon) was fed to the 100 mm linear plasma head at atmospheric pressure. Radio frequency power at 500 W was applied to the electrodes, causing the plasma to be ignited and sustained. The plasma source was then scanned over the indium micro-bumps on the hot plate at a 2.0 mm distance and 1.0 mm/s scan speed.

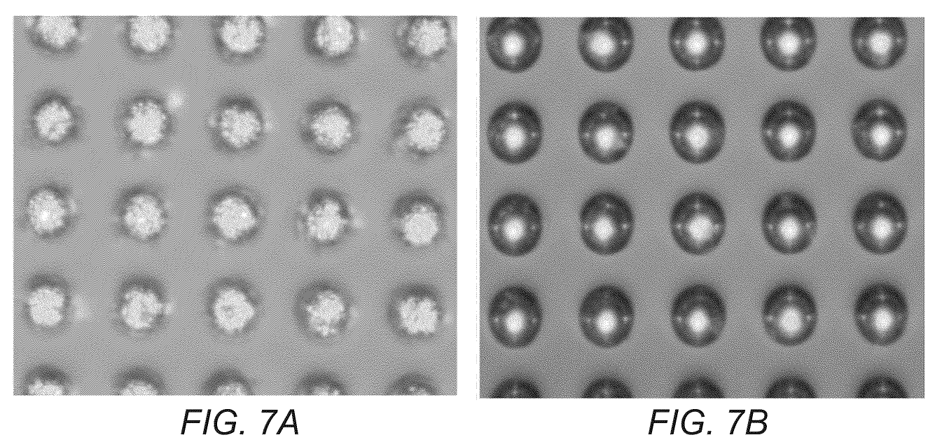

Optical microscope images were taken of the indium micro-bumps before and after exposure to the atmospheric pressure plasma. Shown in FIGS. 7A and 7B are pictures of the bumps before (FIG. 7A) and after (FIG. 7B) plasma treatment. FIG. 7A shows that even when heated past the melting temperature, the indium bumps have a rough texture and flat surface consistent with the as-deposited material. This indicates that the indium oxide surface layer prevented the indium metal from reflowing. By contrast, FIG. 7B shows smooth round balls with a bright reflective top and dark sides. This change of morphology demonstrates that the activated hydrogen from the plasma succeeded in removing the indium oxide and allowing the indium metal to reflow and form spheres.

In another example of the invention, the atmospheric pressure hydrogen and argon plasma was used for indium oxide removal from indium micro-bumps immediately prior to flip chip die bonding at room temperature. No passivation step was required in this case. Indium interconnect arrays were bonded together in two configurations: indium-to-indium bump bonding and indium-bump-to-UBM (under-bump metallization) bonding. The plasma process was compared to the industry standard method of exposing the indium bumps to formic acid vapor in an oven at temperatures between 20° and 225° C. In this case, the indium oxide is removed by forming indium formate that sublimes off the metal surface. After metal oxide removal, the dies containing the indium micro-bump arrays were aligned on top of each other, or on top of a second die containing the under-bump metallization, and bonded together by thermocompression (i.e., using a TCB).

The plasma process was carried out in an inert gas environment purged with argon such that the oxygen concentration was kept below 500 ppm. The 100 mm linear plasma head was fed with 32.4 LPM argon and 7.0 LPM forming gas (5% hydrogen in 95% argon) and powered with 300 W of RF power (at 27.12 MHz). Each die was scanned with the plasma head twice at 1.0 mm/s. Samples were then removed from the inert gas environment, transferred in air to the bonder, and bonded within 30 minutes. The surface temperature of the indium micro-bump arrays did not exceed 70° C. during scanning with the plasma. The ability to remove the indium oxide at such a low temperature is a distinct advantage of the invention.

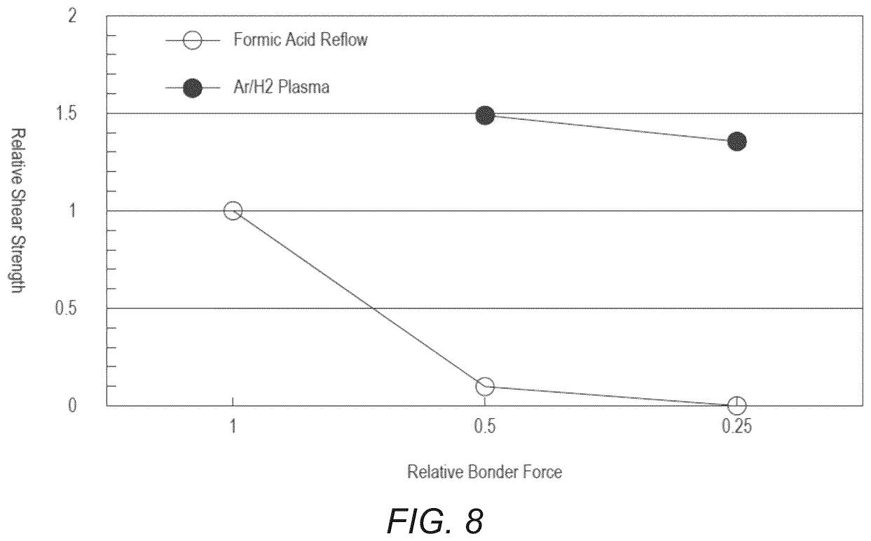

FIG. 8 illustrates the maximum shear strength of the indium-to-indium bonded samples. All shear strength measurements are referenced against a control value obtained using one die treated with formic acid and the other die without any oxide removal process. A relative bonder force of 1.0 is the maximum force the TCB can apply, and it gives a relative shear strength of 1.0. In the case of formic acid reflow, if the bond force is reduced by 50%, then the shear strength falls by 90%. By contrast, when using the atmospheric pressure hydrogen and argon plasma to clean the indium micro-bump arrays before bonding, the bond force can be reduced by 50% or 75% and the relative shear strength is 1.5 or 1.35 times higher than the control. The plasma removal process is an improvement over the industry standard cleaning process in both mechanical shear strength of the interconnects and reduced force required to achieve the bond.

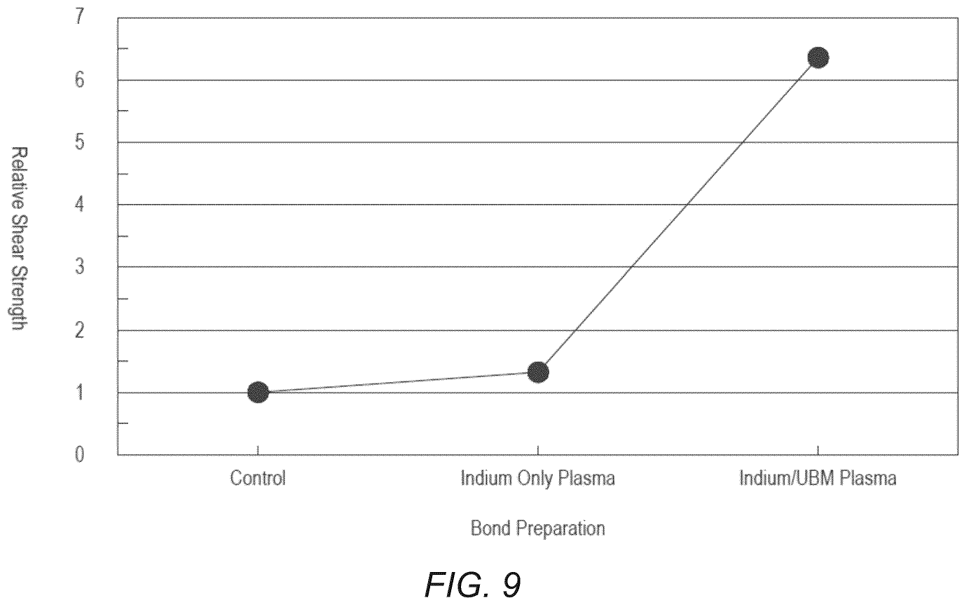

Interconnect assemblies were also tested where a substrate with indium bumps was bonded directly to the UBM (under bump metallization) of another substrate. The UBM material consisted of stacked metal layers with a gold contact layer. FIG. 9 shows the maximum shear stress for three different bond scenarios. The control used as-deposited indium bumps bonded to the UBM. As shown in the figure, treating the UBM was essential for achieving a strong bond to the indium bumps. When plasma was used to process only the indium, the relative shear strength increased from 1.0 to only 1.2. When atmospheric pressure hydrogen and argon plasma was used to treat both the indium bump and the UBM pads, the relative shear strength increased from 1.0 to 6.4. Moreover, for these latter samples, the failure mode observed was not via interconnect bond failure between the indium bumps and the UBM pads, but rather a mechanical failure that resulted in the silicon chip shattering into fragments. Using the plasma process was essential for maximizing the indium to UBM bond strength. The bonding of indium bumps to UBM pads is often done without pretreatment of the UBM gold surface due to gold's inert properties. Nevertheless, these results show that the plasma process is essential not just for oxide metal removal from the indium but also for organic contamination removal from the gold.

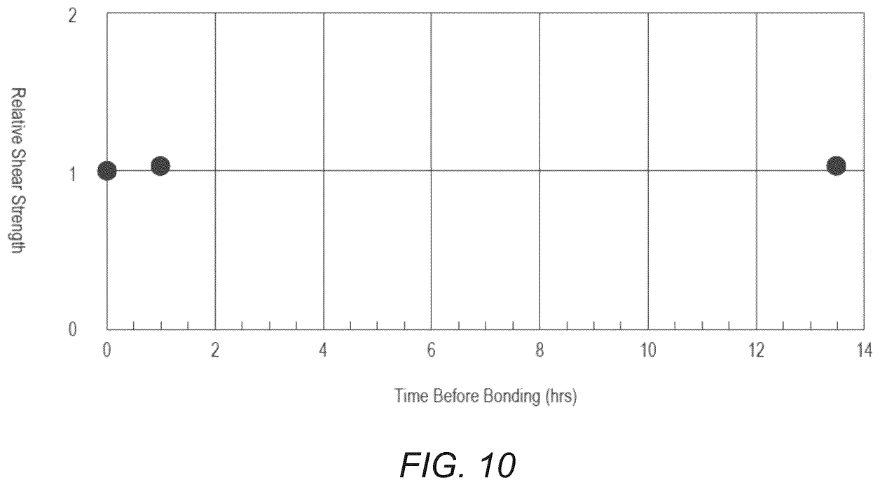

This embodiment of the invention yielded an unexpected improvement over the prior art. One novel result was the ability to maintain the shear strength performance demonstrated above even after significant out-time, where the substrates are stored in contact with air for many hours before thermocompression bonding. FIG. 10 shows the relative shear strength values for indium-to-indium bonded assemblies which were processed with the argon and hydrogen plasma and then held in air for different times prior to TCB. The relative shear strength of the interconnects does not fall significantly with an out time of up to 13.5 hours.

The invention described herein utilizes a single step hydrogen and argon plasma process to remove the indium oxide skin from the indium micro-bumps. The prior art has reported the necessity of generating a nitrogen passivated surface to maintain the bond performance improvement if the sample is exposed to air (Schulte, U.S. Pat. No. 8,567,658, Oct. 29, 2013). The results presented in FIG. 10 demonstrate that said passivation of the indium bumps is unnecessary.

### 4.0 Apparatus for Removing Metal Oxide from Metallic Contacts on Substrates, Dies and Wafers

This section describes some exemplary inert gas purge enclosures which incorporate suitable plasma applicators and inert gas purge environments for electronics assembly, particularly of flip chips. As previously discussed, the plasma applied to prepare the electronics solder joints of an integrated circuit (chip) for interconnect bonding to either a package or another integrated circuit.

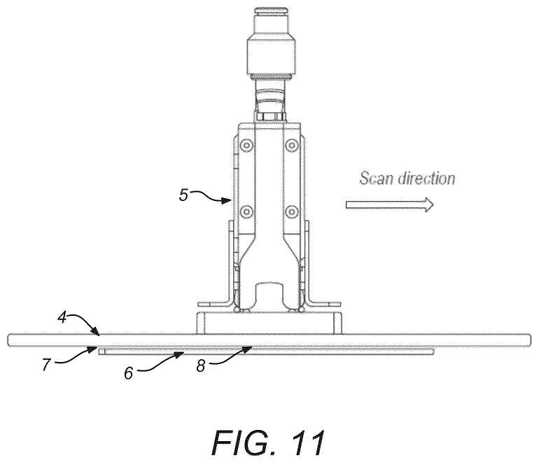

FIG. 11 illustrates an exemplary purge enclosure combined with a plasma applicator for treatment of a substrate or die (i.e., chip) with the atmospheric pressure hydrogen and argon plasma. The plasma head 5 is affixed to a cover plate 4 that is suspended a short distance above a recessed plate 12. The short distance between the cover plate 4 and recessed plate 12 is designed so that the plasma head 5 maybe scanned over a substrate or die without the said plates touching each other. A suitable distance is 0.5 mm, although other distances may be employed and would be obvious to those skilled in the art. The scanning is accomplished by attaching the plasma head 5 and cover plate 4 to a suitable XYZ scanning robot with an adjustable scanning speed in the X and Y directions that may be precisely selected from 0 to 1,000 mm/s. Initially, the plasma head 5 is moved to the left side of the recessed plate 12 so that the gas flow of hydrogen and argon into the recessed volume purges out all the air to a residual amount of oxygen that is less than 500 ppm. Then the plasma is started and the plasma head 5 is moved from left to right scanning completely over the substrate or die and removing any metal oxidation from the array of metal solder balls or bumps or metal contact pads. The plasma may or may not be turned off after the process is complete, depending on throughput and the configuration of the interconnect bonding operation.

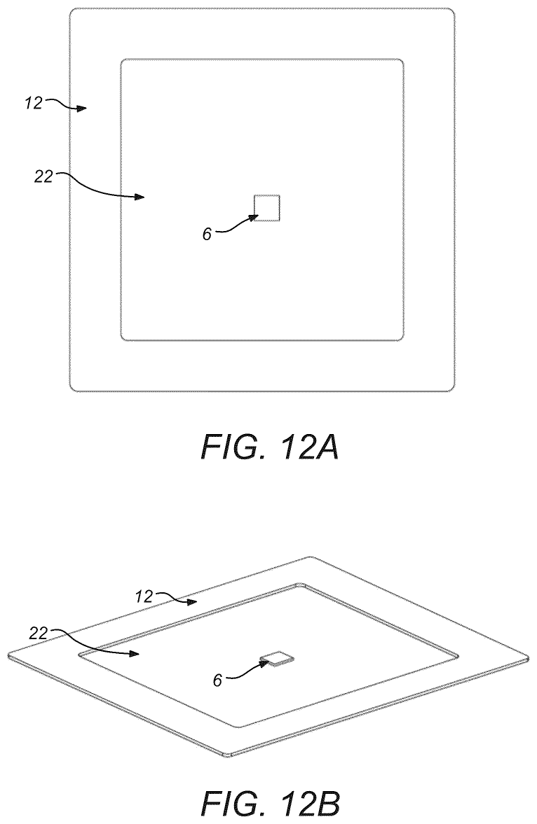

FIGS. 12A and 12B illustrate the recessed plate 12 that creates an enclosed volume 22 where a die 6 has been placed for exposure to the atmospheric pressure hydrogen and argon plasma. The recessed plate 12 comprises four walls defining the enclosed volume 22. The thickness of these walls is designed to be 0.1 to 5.0 mm greater than the thickness of the die 6. This creates the small gap 7 referred to in FIG. 2.

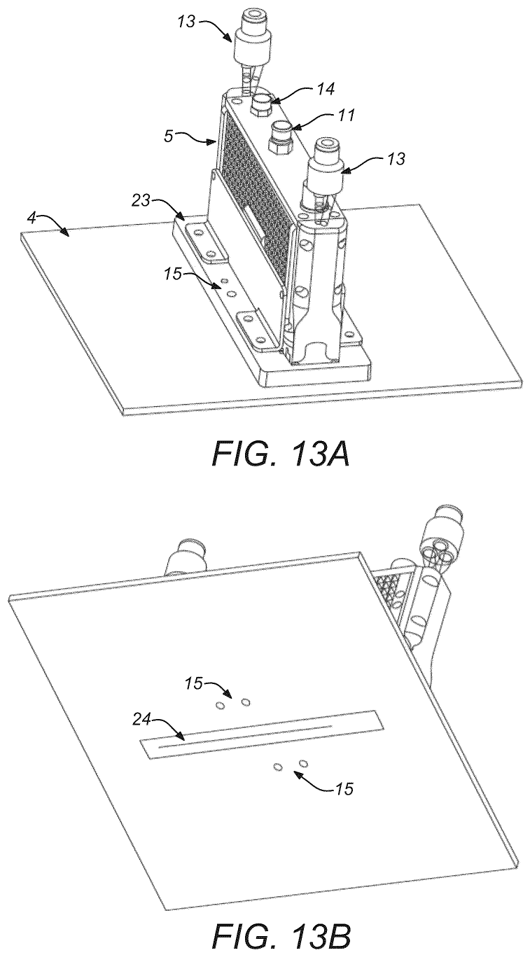

FIGS. 13A and 13B show top isometric and bottom isometric views, respectively, of the atmospheric pressure plasma head 5 affixed to the cover plate 4. The hydrogen and argon gas enters the plasma head 5 at the gas inlet 11. The plasma head 5 has two fittings 13 through which water flows to recirculate through channels inside the device. The water is typically maintained at 60° C. and helps to keep the plasma process at a constant temperature throughout its operation. Other temperatures between 0 and 100° C. may be used and would be obvious to those with ordinary skill in the art. The plasma head 5 illustrated in FIG. 13A also is equipped with an optical sensor 14 to detect the light emission from the plasma, thereby monitoring the plasma performance. The plasma mounting plate 23 contains two holes 15 on each side of the plasma head that serve as inert gas purge inlets. The inert gas is selected from the group argon and nitrogen. One of the holes 15 may alternatively be used to sample the gas and monitor the residual oxygen concentration. The bottom view, FIG. 13B, shows the exit slit 24 through which the activated gases flow out from the plasma head 5. Also shown are the holes 15 for introduction of the inert gas purge. The exit slit 24 is at least as wide as the die, so that when the plasma head scans over the die the entire surface is treated with the activated gas from the atmospheric pressure hydrogen and argon plasma.

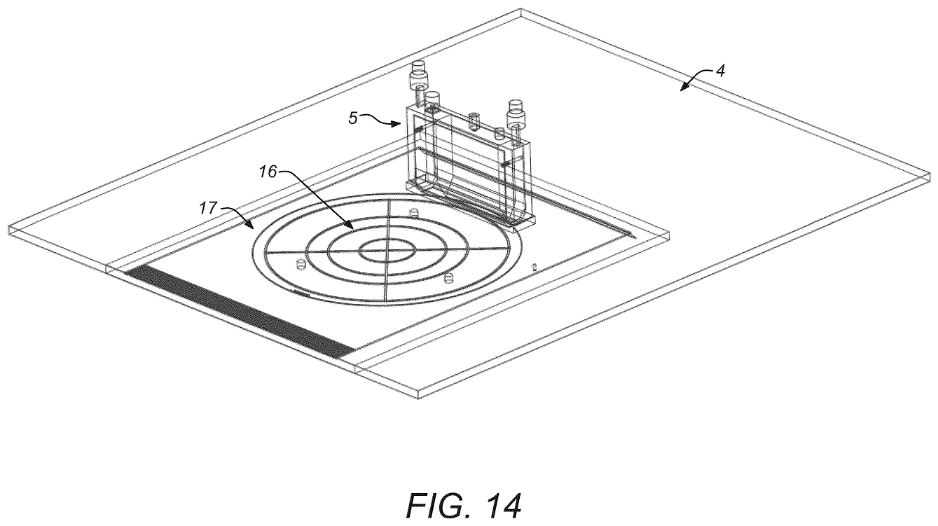

FIG. 14 illustrates an apparatus for processing a wafer with the atmospheric pressure hydrogen and argon plasma in an inert gas environment. The plasma head 5 is affixed to a large cover plate 4 that is suspended above a wafer holder 17. The wafer holder 17 contains a recessed circular plate 16 that the wafer inserts onto. The cover plate 4 has to be at least twice as large as the diameter of the wafer in order for the plasma head 5 to be scanned over a distance in the X and Y direction sufficient to ensure that the wafer is fully scanned with the plasma while maintaining the inert gas environment. For example, if the silicon wafer containing the integrated circuits is 300 mm in diameter, than the cover plate 4 needs to be at least 600 mm wide by 600 mm long.

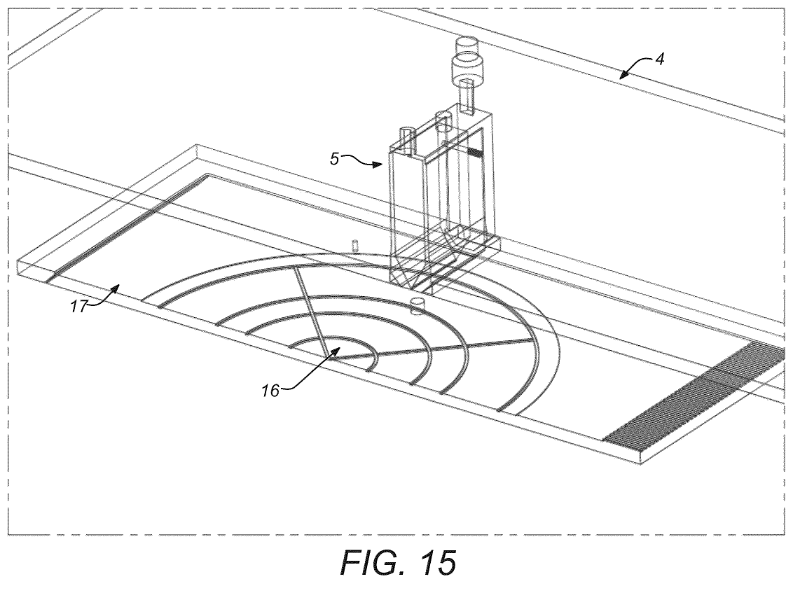

FIG. 15 illustrates a layered cross section of the apparatus for processing a wafer. The plasma head 5 is mounted in the cover plate 4 such that the exit slit for the activated gases to flow out is flush with the bottom of the cover plate 4. The recessed circular plate 16 in the wafer holder 17 are clearly seen in the cross section.

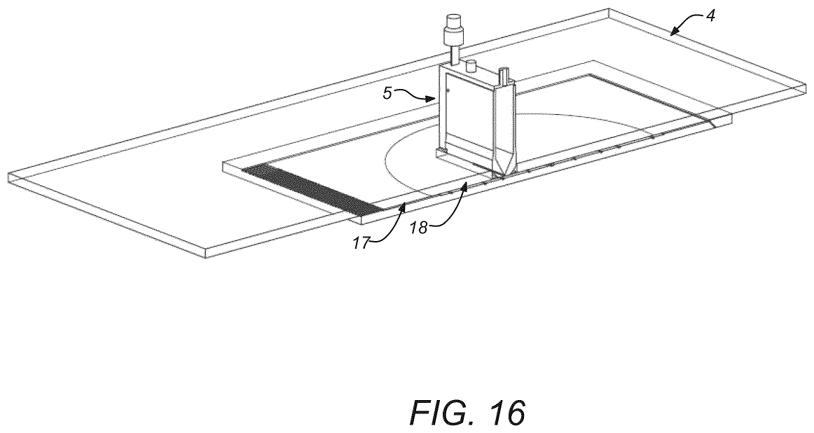

FIG. 16 shows a cut away view of the apparatus for processing a wafer. In this drawing, the silicon wafer 18 has been placed on the recessed circular plate on the wafer holder 17. The depth of the recessed circular plate is substantially the same as the thickness of the wafer so that the surface of the wafer holder is at the same height as the surface of the wafer.

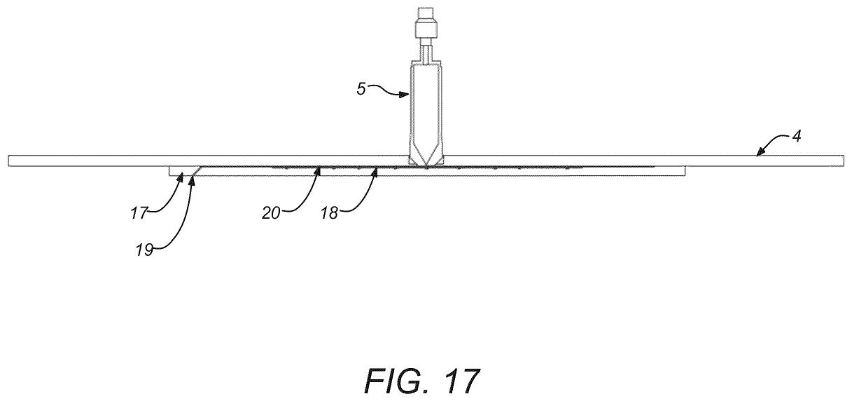

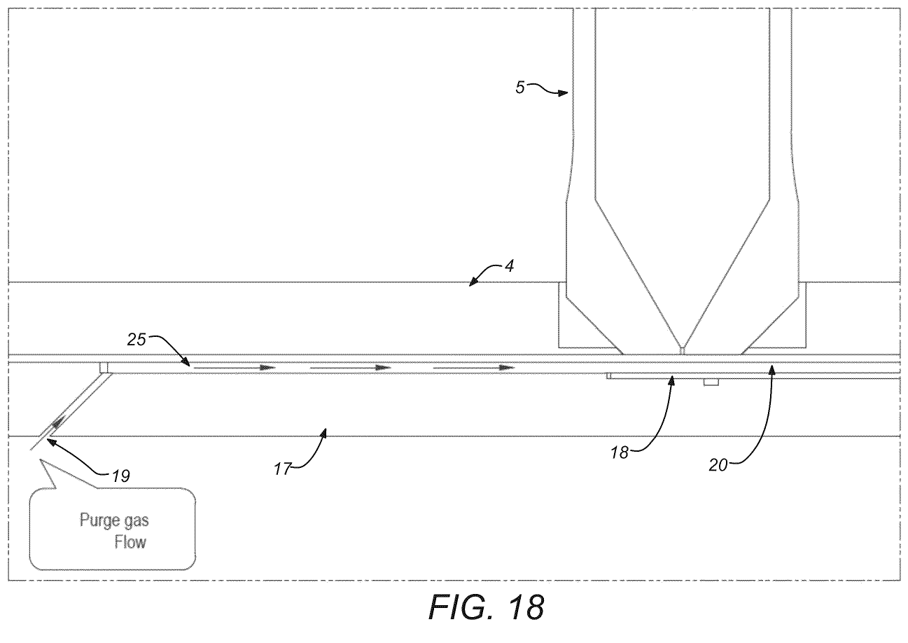

FIG. 17 shows a side view of the apparatus for processing a wafer with the atmospheric pressure hydrogen and argon plasma in an inert gas environment. The wafer holder 17 is configured with a gas inlet 19 for flowing inert gas into the purge volume 20. The purge volume 20 is defined by a small gap between the wafer 18 and the cover plate 4. This small gap is the same gap 7 identified in FIG. 2. FIG. 18 is a side view of the apparatus that has been zoomed in to better illustrate the inert purge gas flow 25 over the wafer. The arrows illustrate the direction of the inert purge gas flow 25 as it enters through the inlet 19 and flows from left to right down the gap and over the wafer 18. The cover plate 4 and plasma head 5 are suspended above the wafer holder 17 and can scan over the wafer 18 without touching the walls of the wafer holder 17. Other suitable designs may be envisioned that would be obvious to those skilled in the art and would accomplish the embodiments of the invention by minimizing the total purge volume 20, while allowing the air to be purged out by the inert gas flow quickly and efficiently.

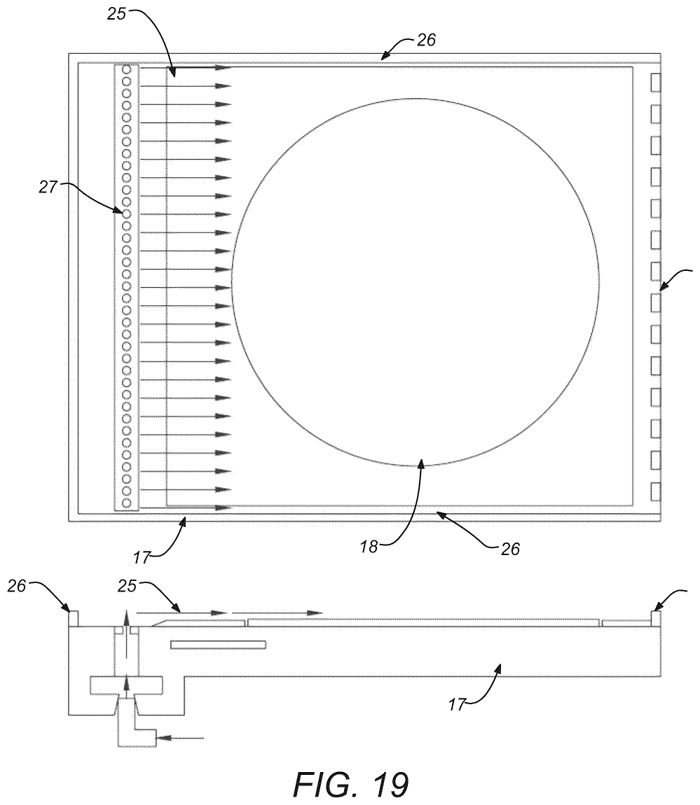

FIG. 19 provides a further illustration of the wafer holder 17. The top view shows the wafer 18 mounted onto the wafer holder 17 with some added space between the wafer 18 and the walls 26. The added space is there to ensure that the purge gas flow 25 over the wafer 18 is not disturbed. The purge gas enters the purge volume through a series of small holes 27 that are spread out across the back of the wafer holder 17. These small holes are configured to generate a uniform flow velocity of inert gas across the diameter of the wafer 18. The gas flows from left to right and exits the wafer holder 17 through a crenulated wall 21 on the right.

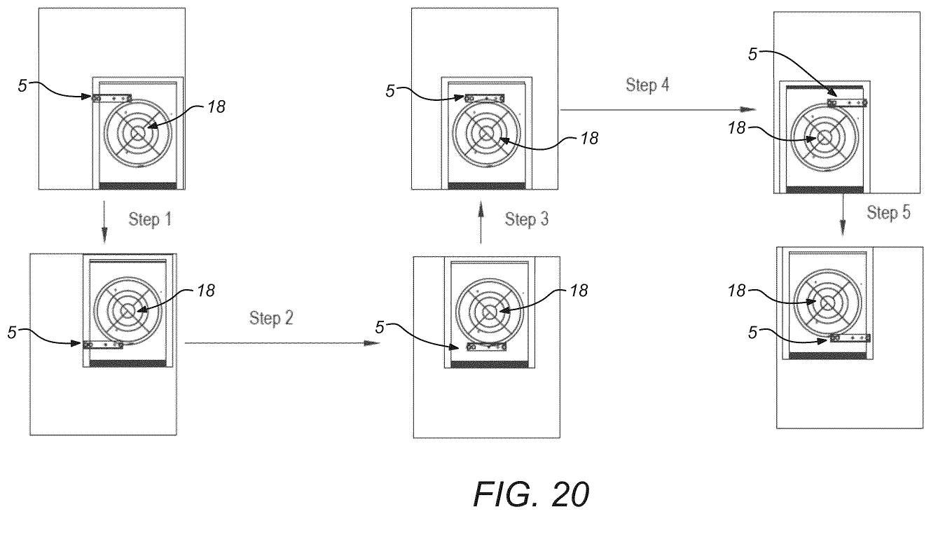

FIG. 20 is a schematic illustrating the path for scanning the plasma head 5 over the wafer 18. For the purposes of illustration, the wafer is assumed to be 300 mm in diameter and the plasma head is configured to generate a linear beam of activated gases 100 mm wide. Initially, the plasma head is positioned in the upper left corner of the wafer holder. The purge flow is turned on to remove the air and generate an inert gas environment, where the inert gas is selected from the group argon and nitrogen. Next the plasma is turned on and the wafer is scanned down the left third of the wafer surface in Step 1. The scan speed can range from 0 to 1,000 mm/s and is determined by the exposure time required to remove oxidation from the surface of the metallic contacts. In Step 2, the plasma head is moved to the center of the wafer holder. Then in Step 3, the plasma head is scanned down the middle third of the wafer. In Step 4, the plasma head is moved to the right side of the wafer holder, and finally in Step 5, the plasma head is scanned down the right third of the wafer. Through this procedure the entire wafer is processed uniformly with the atmospheric pressure hydrogen and argon plasma. Many other scan paths may be devised and would be obvious to those skilled in the art.

### 5.0 Method for Removing Metal Oxide from Metallic Contacts on Substrates, Dies and Wafers

The apparatus described in FIGS. 11-20 was developed to remove copper oxidation from copper structures on 300 mm silicon wafers in an oxygen-free environment. Copper is a common metallic contact. However, other metallic contacts can be treated in a similar manner to remove oxidation from their surfaces, including tin, silver, indium, platinum, palladium, gold and alloys thereof, and would be obvious to those skilled in the art. Furthermore, the novel apparatus can be used for any plasma process on 300 mm wafers where it is desirable to carry out the surface reaction in an oxygen-free environment. Such processes include, but are not limited to, oxide removal, surface modification, thin-film etching and thin-film deposition.

One key aspect of the apparatus of FIGS. 11-20 is the use of a purge that exhibits flow behavior close to plug flow, so that the oxygen level in the chamber is reduced as fast as possible prior to plasma treatment. As shown in FIG. 18, the purge gas flows into the chamber at inlet 19 and flow down a narrow slit 25 from left to right over the wafer 18. In the top view of the apparatus, FIG. 19, a series of small holes 27 are spread out across the back of the chamber to ensure that a uniform velocity of purge gas flow is achieved in the narrow slit 25 across the wafer 18. Those skilled in the art will appreciate that the uniform flow velocity across the width of the chamber is achieved with holes 27 that are small enough to cause a significant pressure drop from the inlet to the outlets of the holes 27. On the opposing side of the chamber the crenulated wall 21 provides an outlet for the purge gas which does not restrict the flow and has a small or negligible pressure drop. The effect of this purge gas flow design is to significantly reduce the time to lower the oxygen level to an acceptable level (for example, to 100 ppm or less) and thereby optimize the oxide removal process. By minimizing the time required to purge out the oxygen, one improves the overall process throughput.

The target concentration of oxygen in the background during hydrogen plasma processing of the wafer is less than 100 parts per million (ppm). When a wafer is inserted into the chamber and placed on the wafer chuck, the lid with the atmospheric plasma source is raised relative to the chuck by at least a centimeter, and air fills the chamber bringing the oxygen concentration to 21 volume %. After placing the wafer on the chuck, the lid is lowered relative to the chuck to a distance of 2.0 mm above the wafer. The width and length of the recessed chamber shown in FIGS. 11-20 is 340 by 440 mm², respectively. This yields an internal volume of 2×340×440/1,000,000=0.3 Liters. By keeping the internal volume small, the oxygen concentration can be quickly lowered to below 100 ppm upon introducing the argon purge flow through the back inlet distributor.

The apparatus presented in FIGS. 11-20 was tested to determine the argon purge flow rate required to remove residual oxygen to a concentration below 100 ppm. A silicon wafer 300 mm in diameter was inserted into the chamber and the lid lowered to a level 2.0 mm above the wafer surface. The side walls around the wafer are less than 2.0 mm high, leaving a small gap between the lid and side walls for the gas to flow out. Next, the argon purge flow was introduced to remove the air that entered the chamber during insertion of the wafer. Shown in TABLE 2 are the results of the purge tests. A flow rate of 100 liters per minute (LPM) over a period of two minutes reduced the oxygen concentration from 21.0% initially to 100 ppm (Test 1). A purge of three minutes at 100 LPM argon reduced the residual oxygen concentration to 20 ppm (Tests 2 and 4). Argon purge flow rates below 100 LPM result in longer times to reduce the oxygen concentration below the 100-ppm target. Increasing the argon purge flow rate to 150 LPM and the purge time to 6 minutes (Test 3), yielded a final oxygen concentration in the chamber of 25 ppm. Turning on the argon flow through the plasma head of 39.5 LPM and combining it with the argon purge flow of 150 LPM, yielded a final oxygen concentration inside the chamber of 17 ppm (Test 5). After the chamber had been purged out for 3 minutes at 150 LPM of argon, the purge flow was reduced to 30 LPM and the argon flow through the plasma was increased to 39.5 LPM (Test 6). This procedure also resulted in a low residual oxygen concentration of 21 ppm.

TABLE 2
Chamber purge conditions.

| | Purge | Purge | Plasma | Final |
|---|---|---|---|---|
| Test No. | flow (LPM) | time (min) | flow (LPM) | oxygen (ppm) |
| 1 | 100 | 2.0 | 0.0 | 100 |
| 2 | 100 | 3.0 | 0.0 | 20 |
| 3 | 150 | 6.0 | 0.0 | 25 |
| 4 | 100 | 3.0 | 0.0 | 25 |
| 5 | 150 | 6.0 | 39.5 | 17 |
| 6 | 30 | 5.5 | 39.5 | 21 |

The flow velocity through the process chamber at 100 and 150 LPM is calculated to be 245.1 and 367.6 cm/s, respectively. From these flow velocities, a Reynolds number of 427 and 641 is calculated. These values are below 2,100, which is well within the laminar flow regime (see for example, R. B. Bird, W. E. Stewart and E. N. Lightfoot, Transport Phenomena, 2^{nd} Edition, Wiley & Sons, New York, 2002, p. 52). In addition, the amount of back mixing of gas in the flow due to Taylor dispersion is minimized at Reynolds numbers below about 600. By minimizing back mixing, the flow behavior more closely approximates plug flow. Of interest is the time it takes to have the oxygen concentration fall below 100 ppm. Two minutes is required at 100 LPM argon purge flow (Re=427). Given a chamber volume of 0.3 Liters, 2 minutes corresponds to 667 volume changes.

Silicon wafers, 100 mm in diameter, were coated with approximately 100 nanometers (nm) of copper, and then placed in an air oven and oxidized sufficiently to create a top layer of copper oxide (CuO) about 40 nm thick. These wafers were placed in a process chamber analogous to that show in FIGS. 11-20 and treated with the atmospheric pressure argon and hydrogen plasma to remove the copper oxide. The procedure was to place a wafer in the center of the wafer chuck, lower the lid, purge out the air over several minutes to below 100 ppm oxygen, strike the hydrogen and argon plasma inside the 100 mm linear beam head, and scan the head over the wafer. After scanning over the 100 mm wafer, the substrate was removed to see if the CuO had been removed by the reaction: CuO+2H=Cu+H₂O. One can tell if the copper oxide was removed by observing the color change from purplish orange to a shiny copper.

The results of hydrogen and argon plasma treatment of the 100 mm, copper-coated silicon wafers are shown in TABLE 3. The first three tests were performed with the substrate held at room temperature, 25° C. The 100 mm linear beam plasma was operated at atmospheric pressure, 550 W radio frequency power (27.12 MHz), 32.8 LPM argon, 7.2 LPM 5% hydrogen in argon, a distance from the exit of the plasma head to the sample surface of 1.5 mm, and scan speeds as listed in TABLE 3. When the argon purge flow is maintained at 150 LPM and combined with the plasma gas flow of 40 LPM, none of the copper oxide is removed at a scan speed of 2 mm/s. Decreasing the purge flow to 30 LPM and combining it with the plasma flow of 40 LPM resulted in an appreciable CuO removal rate. Four scans at 2 mm/s over the 100 mm wafer was sufficient to completely remove the 40-nm-thick CuO layer and covert it back to copper metal.

Tests 5 to 8 in TABLE 3 list the results for atmospheric pressure, argon and hydrogen plasma treatment of the copper oxide on the copper-coated silicon wafers at 150° C. In each case the argon purge flow was initially set at 150 LPM to reduce the oxygen concentration to less than 100 ppm. Then the purge flow was reduced to 30 LPM and the plasma struck and scanned over the 100 mm wafer. It was observed that all the CuO is removed by translating the plasma head over the wafer 4 times at a scan speed of 10 mm/s, or equivalently 2 times at a scan speed of 5 mm/s (Tests 7 and 8).

TABLE 3
Process conditions for CuO removal from 100 mm wafers.

| | Chuck | | | | | | |
|---|---|---|---|---|---|---|---|
| | temper- | Purge | Plasma | Plasma | Scan | | |
| Test | ature | flow | Power | flow | speed | | Oxide |
| No. | (° C.) | (LPM) | (W) | (LPM) | (mm/s) | Scans | Removed |
| 1 | 25 | 150 | 550 | 40 | 2 | 1 | None |
| 2 | 25 | 30 | 550 | 40 | 2 | 1 | One third |
| 3 | 25 | 30 | 550 | 40 | 2 | 4 | All |
| 5 | 150 | 30 | 550 | 40 | 10 | 1 | One third |
| 6 | 150 | 30 | 550 | 40 | 10 | 2 | Half |
| 7 | 150 | 30 | 550 | 40 | 10 | 4 | All |
| 8 | 150 | 30 | 550 | 40 | 5 | 2 | All |

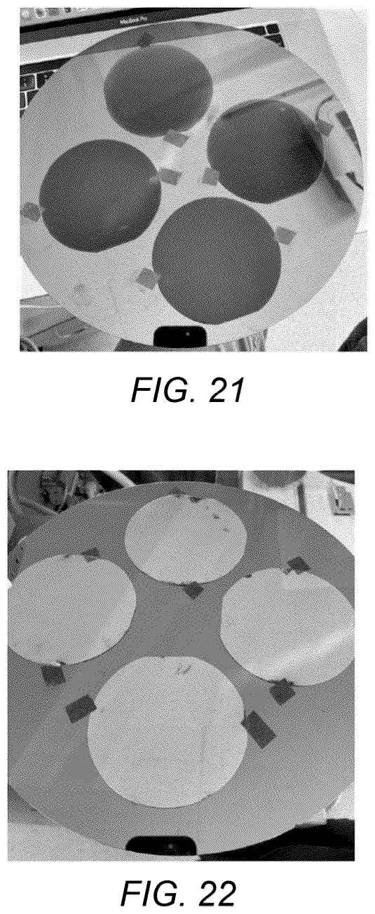

Another set of tests were performed in which four 100 mm copper-coated silicon wafers were placed on a 300 mm silicon wafer and processed in the apparatus as described above. These results are presented in TABLE 4. A picture of the four 100 mm wafers on a larger 300 mm wafer is shown in FIG. 21. The reddish brown to purple color of the copper indicates that there is a CuO film on the surface between 41 and 46 nm thick (see J. Lee, T. S. Williams and R. F. Hicks, “Atmospheric pressure plasma reduction of copper oxide to copper metal,” J. Vac. Sci. Technol. A, vol. 39, p. 023001 (2021)). This sample was placed in the apparatus on the sample chuck heated to 150° C., and the air purged out with argon flow at 150 LPM to reduce the oxygen concentration below 100 ppm. Then the argon purge flow was reduced to 30 LPM, the atmospheric plasma struck and maintained at 580 W RF power with 55 LPM plasma gas flow comprising about 1.0% hydrogen and 99.0% argon, and the plasma head scanned over the wafer in a manner sufficient to process the entire sample surface.

TABLE 4
Process conditions for CuO removal from 300 mm wafers

| | Chuck | Purge | Plasma | Plasma | Scan | |
|---|---|---|---|---|---|---|
| Test | temperature | flow | Power | flow | speed | Oxide |
| No. | (° C.) | (LPM) | (W) | (LPM) | (mm/s) | Removed |
| 1 | 150 | 30 | 580 | 55 | 5 | All |
| 2 | 150 | 30 | 580 | 55 | 5 | All |
| 3 | 150 | 0 | 580 | 55 | 5 | All |

An example procedure used to scan the 100 mm plasma head over the 300 mm wafer is shown in FIG. 20. In step 1, the plasma head is at the back left side of the chamber and is scanned to the front of the chamber over a 100-mm-wide strip on the left side of the 300 mm wafer. In step 2, the plasma head is translated to the right 100 mm so that it is positioned at the center of the 300 mm wafer. In step 3, the plasma head is scanned down the center of the 300 mm wafer from the front of the chamber to the back, processing a 100-mm-wide strip. In step 4, the plasma head is translated again to the right 100 mm so that it is positioned on the right side of the 300 mm wafer. In step 5, the plasma head is scanned down the right side of the 300 mm wafer from the back to the front of the chamber, thereby processing another 100-mm-wide strip and thereby completing the process.

TABLE 4 presents the results of three separate tests whereby four 100 mm copper-coated silicon wafers were processed with the atmospheric pressure, argon and hydrogen plasma by the methods described in the preceding paragraphs. In this case, the scan procedure was to take 50 mm steps with each scan down the 300 mm wafer, instead of 100 mm steps. The total number of scans required in this case were 5 instead of 3. The scan speed of the plasma head relative to the substrate was 5 mm/s. In each of the 3 tests, the copper oxide film, 41 to 46 nm thick, was completely removed. This was evident by inspecting the wafers and seeing a bright, shiny copper color. An example of the four Cu-coated Si wafers before and after processing with the argon and hydrogen plasma is shown in FIGS. 21 and 22, respectively.

To summarize the foregoing process respecting the purge of oxygen from the chamber, the oxygen is pushed out by the argon coming in and flowing out the end. Some oxygen can escape around the edges (i.e. the gap with the coverplate), but only a negligible amount because there is a pressure drop there. However, the crenulated wall (or any similar expanding outlet) allows the gas to flow out with minimal pressure drop. On the inlet side, the flow straightener sets up a uniform velocity across the diameter of the 300 mm wafer of the example.

The example presented above is intended to illustrate one embodiment of the invention: the method of employing an apparatus with an inert gas purge and an atmospheric pressure, hydrogen and argon plasma to remove the oxidation from metallic contacts on a wafer. Other embodiments of the invention would be employing an apparatus with an inert gas purge and an atmospheric pressure, hydrogen and argon plasma to remove the oxidation from metallic contacts on dies and substrates. The metallic contacts may be comprised of metals selected from the group copper, tin, indium, silver, platinum, palladium, gold and alloys thereof. Many other embodiments may be practiced and would be evident to those skilled in the art.

This concludes the description, including the preferred embodiments of the invention. The foregoing description including the preferred embodiments of the invention has been presented for the purposes of illustration and description. It is not intended to be exhaustive or to limit the invention to the precise forms disclosed. Many modifications and variations are possible within the scope of the foregoing teachings. Additional variations of the invention may be devised without departing from the inventive concept as set forth in the following claims.

What is claimed is:

1. A method for applying a low-temperature, atmospheric pressure plasma to a surface, comprising:
enclosing the surface in a closable chamber having surrounding sidewalls and a movable coverplate above the surrounding sidewalls by a gap to form the closable chamber such that the gap with the surrounding sidewalls is maintained under movement of the coverplate;
purging the closable chamber through a purge gas inlet along a side of the closable chamber comprising a flow straightener for increasing a flow rate of a purge gas into the closable chamber from the purge gas inlet through the closable chamber and out a purge gas outlet along an opposing side of the closable chamber;
wherein a plasma source is affixed to the coverplate to deliver and the purge gas achieves plug flow through the closable chamber prior to activation of the plasma source to apply the low-temperature, atmospheric pressure plasma to the surface.

2. The method of claim 1, wherein purging the internal volume yields a concentration of oxygen within the chamber of less than 100 parts per million.

3. The method of claim 1, wherein the flow straightener comprises a plurality of inlet ports in a line along the side of the closable chamber.

4. The method of claim 1, wherein the low-temperature, atmospheric pressure plasma is generated using radio frequency power at 13.56 or 27.12 MHz.

5. The method of claim 1, wherein the plasma treatment is selected from a plasma treatment group comprising removing metal oxide, surface cleaning, surface activation, etching of a thin film on the substrate, and deposition of a thin film on the substrate.

6. The method of claim 1, wherein the purge gas comprises argon.

7. The method of claim 6, wherein the flow rate of the argon is at least 30 gpm.

8. The method of claim 1, further comprising a movable coverplate above the surrounding sidewalls by a gap to form the closable chamber such that the gap with the surrounding sidewalls is maintained under movement of the coverplate;
wherein the plasma source is affixed to the coverplate to deliver the low-temperature, atmospheric pressure plasma to the surface through an opening in the coverplate.

9. The method of claim 8, wherein the coverplate and plasma head are scanned over the metallic contact on the substrate at a maximum rate from 2 to 10 mm/s.

10. The method of claim 8, wherein the gap of the coverplate above the surrounding sidewalls of the recess to form an internal volume of the chamber is between 0.5 and 1 mm.

11. The method of claim 8, wherein the surrounding sidewalls have a height between 0.5 and 1 mm.

12. The method of claim 1, wherein the surface is of a semiconductor die, semiconductor wafer, or semiconductor package including metal interconnects, and the hydrogen radicals remove the metal oxide on surfaces of the metal interconnects such that the metal interconnects are joinable by application of heat and pressure.

13. The method of claim 12, wherein the metal interconnects on the semiconductor die, the semiconductor wafer, or the semiconductor package are disposed in a two-dimensional array.

14. The method of claim 12, wherein the metal interconnects comprise one or more metals selected from a group of copper, tin, indium, silver, gold, platinum, palladium, nickel and gallium.

15. A method for modifying a surface of a substrate with a low-temperature, atmospheric pressure plasma in an inert gas environment, comprising:
enclosing the substrate in a chamber having surrounding sidewalls and a movable coverplate above the surrounding sidewalls with a gap therebetween;
affixing a plasma source to the movable coverplate having a plasma outlet through the coverplate into the chamber;
purging the chamber with inert gas sufficient to reduce an oxygen concentration of the chamber to several orders of magnitude less than in air, the inert gas entering through and inlet to the chamber and exiting through an outlet from the chamber; and
scanning and activating the plasma source affixed to the cover plate over the substrate, such as to expose the surface of the substrate to a reactive species generated by the plasma delivered through the plasma outlet;
wherein an inert gas environment is maintained within the chamber throughout the scanning.

16. The method of claim 15, wherein purging the internal volume yields the oxygen concentration within the chamber of less than 1,000 parts per million.

17. The method of claim 15, wherein the gap is maintained between 01. and 2.0 millimeters.

18. The method of claim 15, wherein the purge gas is selected from the group comprising argon and nitrogen.

19. The method of claim 15, wherein the atmospheric pressure plasma is fed with at least argon and hydrogen.

20. The method of claim 15, where in the atmospheric pressure plasma is generated using radio frequency power at 13.56 or 27.12 MHz.

21. The method of claim 15, wherein the substrate is selected from the group comprising 300 mm silicon wafers, 300 mm glass wafers, dies on 400 mm tape frames, and glass panels larger than 400 mm on a side.

22. The method of claim 15, wherein the volume of gas inside the chamber is less than 1.0 liter.

23. The method of claim 15, wherein the Reynolds number calculated for the purge gas flow inside the chamber is less than 1,000.

24. The method of claim 15, where in the surface modification is selected from the group comprising cleaning contaminants off the surface, removal of metal oxidation from interconnect structures, etching a thin layer off the surface, and deposition of a thin film.

25. An apparatus for modifying a surface of a substrate with a low-temperature, atmospheric pressure plasma in an inert gas environment, comprising:
a chamber for enclosing the substrate, the chamber having surrounding sidewalls and a movable coverplate above the surrounding sidewalls with a gap therebetween;
a plasma source affixed to the movable coverplate and having a plasma outlet through the movable coverplate into the chamber;
an inlet to the chamber for purging the chamber with inert gas sufficient to reduce an oxygen concentration of the chamber to several orders of magnitude less than in air; and
an outlet from the chamber for the inert gas; and
a scanning mechanism for scanning the plasma source by moving the movable coverplate over the substrate and operating the plasma source such as to expose the surface of the substrate to a reactive species generated by the plasma delivered through the plasma outlet;
wherein an inert gas environment is maintained within the chamber throughout the scanning.
